(19) United States
(12) Patent Application Publication
(10) Pub. No.: US 2022/0254706 A1
(43) Pub. Date: Aug. 11, 2022

(54) SEMICONDUCTOR DEVICE

(71) Applicant: ABLIC Inc., Tokyo (JP)

(72) Inventor: Kiyoaki KADOI, Tokyo (JP)

(21) Appl. No.: 17/568,327

(22) Filed: Jan. 4, 2022

(30) Foreign Application Priority Data
Feb. 9, 2021 (JP) 2021-019100

(51) Int. Cl. H01L 23/495; H01L 23/31

(52) U.S. Cl. CPC H01L 23/49555; H01L 21/4842; H01L 23/3107; H01L 23/49582

(57) ABSTRACT

Provided a semiconductor device which is covered by an encapsulating resin into a cuboid shape, and has a plurality of lead portions partially exposed from side surfaces and a bottom surface thereof, the semiconductor device having cutout portions formed in the encapsulating resin along edges formed by the side surfaces and the bottom surface, each of the plurality of lead portions having a first exposed surface which is coplanar with one of the side surfaces, and is exposed from the one of the side surfaces; and second exposed surfaces which are surfaces that are adjacent to and on both sides of the first exposed surface, and are exposed from the one of the cutout portions.

### RELATED APPLICATIONS

This application claims priority to Japanese Patent Application No. 2021-019100, filed on Feb. 9, 2021, the entire content of which is incorporated herein by reference.

### BACKGROUND OF THE INVENTION

### 1. Field of the Invention

The present invention relates to a semiconductor device.

### 2. Description of the Related Art

As a method of a back-end process for a semiconductor device, there is known a method called “mold array package (MAP)” in which a plurality of device areas are collectively covered by an encapsulating resin, and the encapsulating resin is cut into a product size for singulation.

As an example of the MAP method, there is disclosed a technology in which a lead frame having a shape in which adjacent device areas are connected by a connecting portion is formed by molding, and laser is irradiated along grooves formed in the connecting portion for singulation (see U.S. Pat. No. 8,017,447).

Further, as another example of the MAP method, there is disclosed a technology in which, for a lead exposed from a bottom surface of a sealing body that seals a semiconductor chip, the sealing body around the lead is irradiated with laser to form grooves and expose side surfaces of the lead, to thereby increase mounting strength of a semiconductor device (see Japanese Patent Application Laid-open No. 2013-143445).

In a product form called “leadless package” manufactured by the MAP method described above, in a case in which the lead frame is thin, because of small areas of lead side surfaces being cut surfaces obtained by singulation, fillets are hard to be formed on the lead side surfaces. As a result, bonding strength with respect to a mounting substrate may be low in some cases.

### SUMMARY OF THE INVENTION

In view of the above-mentioned circumstances, it is an object of at least one aspect of the present invention to provide a semiconductor device with which bonding strength with respect to a mounting substrate can be increased.

According to at least one embodiment of the present invention, there is provided a semiconductor device which is covered by an encapsulating resin into a cuboid shape, and has a plurality of lead portions partially exposed from side surfaces and a bottom surface thereof, the semiconductor device having cutout portions formed in the encapsulating resin along edges formed by the side surfaces and the bottom surface, each of the plurality of lead portions having a first exposed surface which is coplanar with one of the side surfaces, and is exposed from the one of the side surfaces; and second exposed surfaces which are surfaces that are adjacent to and on both sides of the first exposed surface, and are exposed from the one of the cutout portions.

According to the at least one aspect of the present invention, it is possible to provide the semiconductor device with which the bonding strength with respect to the mounting substrate can be increased.

### BRIEF DESCRIPTION OF THE DRAWINGS

FIG. 1 is a perspective view for illustrating the structure on a mounting surface side of a semiconductor device according to a first embodiment of the present invention.

FIG. 2 is an enlarged perspective view for illustrating the structure of a lead portion of the semiconductor device according to the first embodiment.

FIG. 3 is a schematic sectional view taken along the line III-III of FIG. 1.

FIG. 4 is a partial perspective view for illustrating a state before the semiconductor device according to the first embodiment is mounted on a substrate.

FIG. 5 is a partial perspective view for illustrating a state after the semiconductor device according to the first embodiment is mounted on the substrate.

FIG. 6 is an explanatory view for illustrating a cross section taken along the line III-III of FIG. 1 after the semiconductor device according to the first embodiment is mounted on the substrate.

FIG. 7A is an explanatory view for illustrating a method of manufacturing the semiconductor device according to the first embodiment.

FIG. 7B is an explanatory view for illustrating the method of manufacturing the semiconductor device according to the first embodiment.

FIG. 7C is an explanatory view for illustrating the method of manufacturing the semiconductor device according to the first embodiment.

FIG. 7D is an explanatory view for illustrating the method of manufacturing the semiconductor device according to the first embodiment.

FIG. 7E is an explanatory view for illustrating the method of manufacturing the semiconductor device according to the first embodiment.

FIG. 7F is an explanatory view for illustrating the method of manufacturing the semiconductor device according to the first embodiment.

FIG. 7G is an explanatory view for illustrating the method of manufacturing the semiconductor device according to the first embodiment.

FIG. 8 is a perspective view for illustrating the structure on a mounting surface side of a semiconductor device according to a modification example of the first embodiment.

FIG. 9 is an explanatory view for illustrating a method of manufacturing the semiconductor device according to the modification example of the first embodiment.

FIG. 10 is a perspective view for illustrating the structure on a mounting surface side of a semiconductor device according to a second embodiment of the present invention.

FIG. 11 is a perspective view for illustrating the structure on a mounting surface side of a semiconductor device according to a modification example of the second embodiment.

### DETAILED DESCRIPTION OF THE PREFERRED EMBODIMENTS

Now, embodiments of the present invention are described in detail with reference to the drawings.

In the drawings, like components are denoted by like reference symbols, and duplicate description thereof may be omitted in some cases. Further, in the drawings, an X direction, a Y direction, and a Z direction are orthogonal to one another. A direction including the X direction and a direction (−X direction) opposite to the X direction is referred to as an “X-axis direction,” a direction including the Y direction and a direction (−Y direction) opposite to the Y direction is referred to as a “Y-axis direction,” and a direction including the Z direction and a direction (−Z direction) opposite to the Z direction is referred to as a “Z-axis direction” (height direction, thickness direction). In this respect, in the following embodiments, a surface on a mounting surface side with respect to a mounting substrate may be referred to as a “bottom surface,” and a normal direction of the bottom surface is defined as the Z-axis direction.

The drawings are schematically illustrated, and may not be drawn to scale in terms of a ratio of a width, a length, and a depth, for example.

### <Semiconductor Device>

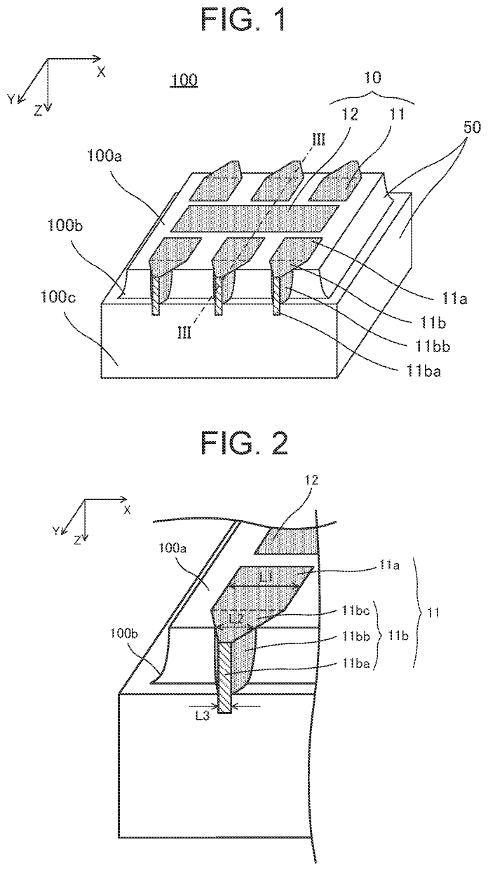

FIG. 1 is a perspective view for illustrating the structure on a mounting surface side of a semiconductor device according to a first embodiment of the present invention.

As illustrated in FIG. 1, a semiconductor device 100 is manufactured by an MAP method, and has the structure of a 6-pin Dual-Flat No-leads (DFN) leadless package.

Specifically, the semiconductor device 100 is covered by an encapsulating resin 50 into a cuboid shape, and has a step 100b formed by cutout portions which are formed by laser processing in the encapsulating resin 50 along edges formed by a bottom surface 100a and side surfaces 100c. In the semiconductor device 100, a plurality of lead portions 11 are partially exposed from the bottom surface 100a, the step 100b, and the side surfaces 100c.

A lead frame 10 includes six lead portions 11 and a die pad 12.

The six lead portions 11 are exposed from the bottom surface 100a of the semiconductor device 100, and in plan view of the bottom surface 100a, three of the lead portions 11 are arrayed along each of two long sides of the die pad 12 which is arranged near the center of the bottom surface 100a. Each of the lead portions 11 has the structure in which a rectangular portion 11a and a tip portion 11b are integral and have the same height.

A shape of the rectangular portion 11a is a rectangular shape in plan view of the bottom surface 100a of the semiconductor device 100, and only a bottom surface of the rectangular portion 11a is exposed from the encapsulating resin 50. The rectangular portions 11a are arrayed on the die pad 12 side.

The tip portion 11b is arranged on a side opposite to the die pad 12 side of the rectangular portion 11a. A shape of the tip portion 11b is a trapezoid shape in plan view of the bottom surface 100a, and a lower base which is longer than an upper base of the trapezoid is in contact with the rectangular portion 11a.

A first exposed surface 11ba which is a surface of the tip portion 11b on the side surface 100c side of the semiconductor device 100 is coplanar with the side surface 100c of the semiconductor device 100, and is exposed from the side surface 100c. The first exposed surface 11ba is provided also in extension to the side surface 100c in which the step 100b is not provided, and is entirely exposed from the side surface 100c. Further, second exposed surfaces 11bb which are surfaces adjacent to and on both sides of the first exposed surface 11ba are exposed from the step 100b including curved surfaces along one of the curved surfaces.

The die pad 12 is arranged near the center of the bottom surface 100a of the semiconductor device 100, and a bottom surface of the die pad 12 is exposed. With this configuration, the die pad 12 can radiate heat of a semiconductor chip 20 which is mounted on an upper surface thereof from the bottom surface.

FIG. 2 is an enlarged perspective view for illustrating the structure of a lead portion of the semiconductor device according to the first embodiment.

As illustrated in FIG. 2, a width L1 of the rectangular portion 11a, a widest width L2 of an area in which the tip portion 11b is exposed from the encapsulating resin 50, and a width L3 of the first exposed surface 11ba in the X direction become narrower in the stated order (L1>L2>L3).

An angle formed by the first exposed surface 11ba and each of the second exposed surfaces 11bb may be selected as appropriate without particular limitation, but from the viewpoint of increasing visibility of a solder joint portion, is preferably an obtuse angle as in the first embodiment.

A height (width in the Z direction) of the step 100b may be selected as appropriate without particular limitation, but is preferably equal to or less than a height of the first exposed surface 11ba.

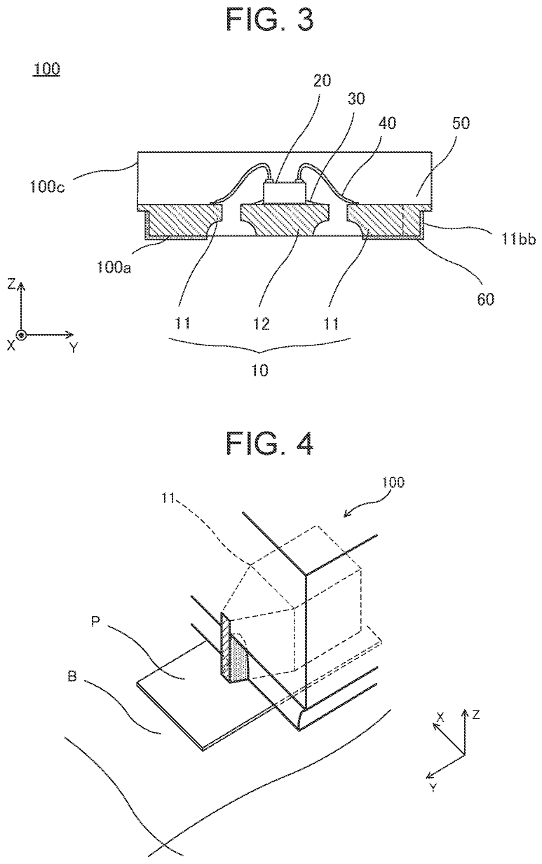

FIG. 3 is a schematic sectional view taken along the line III-III of FIG. 1. The line III-III of FIG. 1 is a straight line that does not pass through the first exposed surface 11ba, but passes through the second exposed surface 11bb.

As illustrated in FIG. 3, the lead frame 10 is arranged on the bottom surface 100a side of the semiconductor device 100.

The lead portions 11 are arranged along the side surfaces 100c of the semiconductor device 100. In a side surface on the die pad 12 side of each of the lead portions 11, a cutout for prevention of falling off is formed.

The die pad 12 is arranged to be sandwiched by the lead portions 11. In side surfaces on the lead portion 11 sides of the die pad 12, cutouts for prevention of falling off are formed.

A material of the lead frame 10 may be selected as appropriate without particular limitation, and examples thereof include a Cu alloy and an Fe—Ni alloy.

A bottom surface and the second exposed surfaces 11bb of each of the lead portions 11 are covered by a metal film 60 having solder wettability. It is preferred that the second exposed surfaces 11bb, in particular, of those surfaces be covered by the metal film 60 so that solder is easier to climb up.

The metal film 60 is a plating film made of, for example, Sn, Pb—Sn, Sn—Bi, or Sn—Ag—Cu.

The first exposed surface 11ba is not covered by the metal film 60.

The semiconductor chip 20 is bonded to the upper surface of the die pad 12 with a die bonding material 30.

The semiconductor chip 20 may be selected as appropriate without particular limitation, and examples thereof include a silicon device, a SiC device, and a compound device.

The die bonding material 30 may be selected as appropriate without particular limitation, and examples thereof include Ag paste, high-melting-point solder, a sintered metal, insulating paste, and a die attach film (DAF). Further, the die bonding material is sometimes also referred to as a “die attach material.”

Wires 40 electrically connect bonding pads provided on an upper surface of the semiconductor chip 20 and the lead portions 11. The wires are sometimes also referred to as “electroconductive members” or “wiring materials.”

A material of the wires 40 may be selected as appropriate without particular limitation, and examples thereof include Au, Cu, Al, Ag, or an alloy thereof.

In the first embodiment, the wires 40 are used to electrically connect the semiconductor chip 20 and the lead portions 11. However, the present invention is not limited thereto, and flip chip mounting using bumps may be adopted, for example.

The encapsulating resin 50 protects a part of the lead frame 10, the semiconductor chip 20, the die bonding material 30, and the wires 40, and forms an external shape of the semiconductor device 100.

The encapsulating resin 50 may be selected as appropriate without particular limitation, and examples thereof include a thermosetting epoxy based resin.

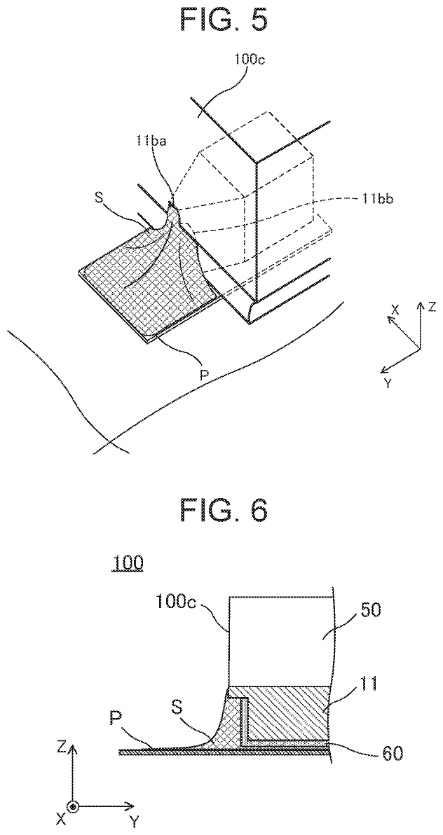

FIG. 4 is a partial perspective view for illustrating a state before the semiconductor device according to the first embodiment is mounted on the substrate. FIG. 5 is a partial perspective view for illustrating a state after the semiconductor device according to the first embodiment is mounted on the substrate. FIG. 6 is an explanatory view for illustrating a cross section after the semiconductor device according to the first embodiment is mounted on the substrate.

When the semiconductor device 100 is mounted with solder and with a positional relationship of a lead portion 11 with respect to a conductor pattern P arranged on a mounting substrate B made of glass epoxy as illustrated in FIG. 4, a result as illustrated in FIG. 5 and FIG. 6 is obtained. In other words, when the lead portion 11 is connected to the conductor pattern P with solder S, the solder S climbs up the first exposed surface 11ba and the second exposed surfaces 11bb which are illustrated in FIG. 2 to form a fillet having such a satisfactory shape as to flare downward from an upper portion of the first exposed surface 11ba. With this configuration, the semiconductor device 100 is strongly joined to the mounting substrate B, and bonding strength with respect to the mounting substrate B can be increased.

In the first embodiment, because surfaces of the second exposed surfaces 11bb are covered by the metal film 60 having satisfactory solder wettability, even under a state in which the first exposed surface 11ba is not covered by the metal film, a fillet having a more satisfactory shape can be formed. If the conductor pattern P has a rectangular shape having a width that is substantially the same width as the width L1 of the rectangular portion 11a, the solder S can climb up the second exposed surfaces 11bb to form a satisfactory fillet.

Further, with the above-mentioned shape of the tip portion 11b of the lead portion 11, even in a semiconductor device in which a width of the lead portion 11 is narrow and the number of lead portions 11 is large, visual inspection of joint portions with respect to the mounting substrate B can easily be performed.

### (Method of Manufacturing Semiconductor Device)

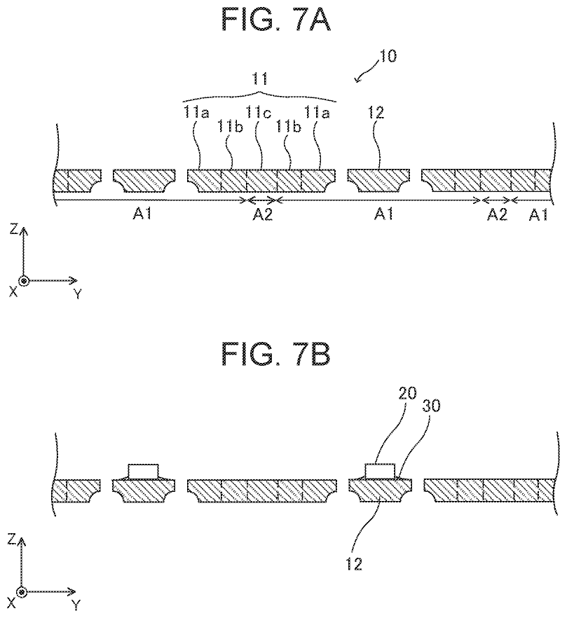

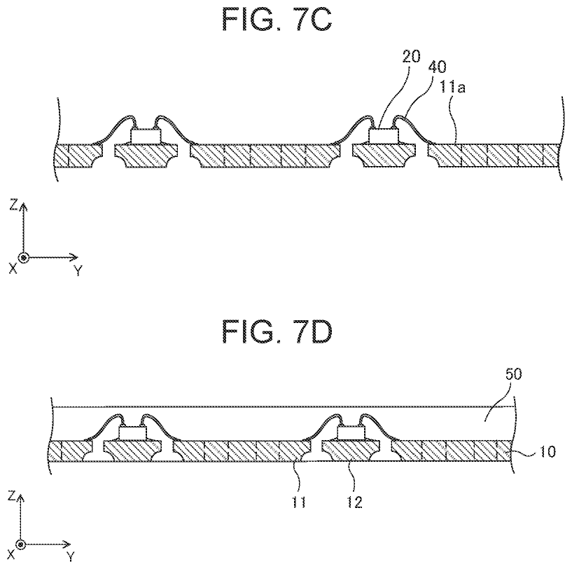

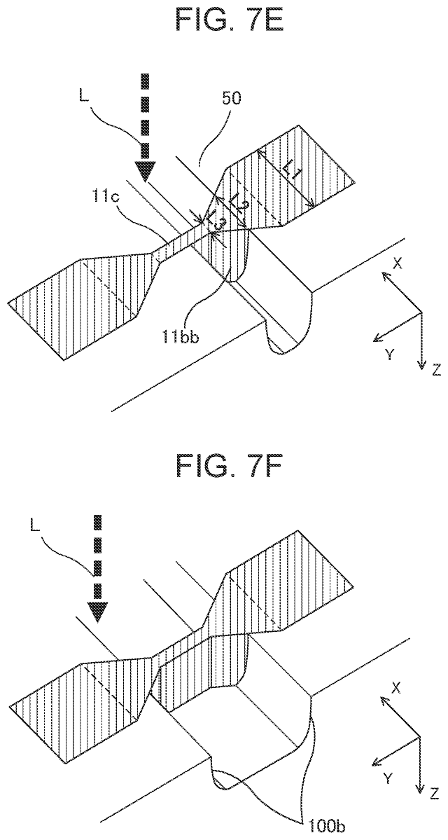

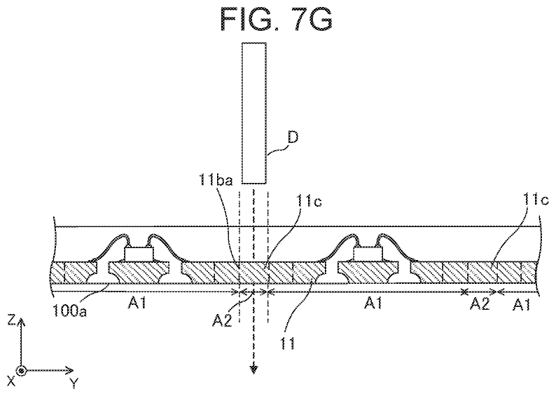

FIG. 7A to FIG. 7G are explanatory views for illustrating a method of manufacturing the semiconductor device according to the first embodiment.

### <1. Preparation of Lead Frame>

First, as illustrated in FIG. 7A, the lead frame 10 prepared in the first place has the following two areas: device areas A1 in each of which the semiconductor device 100 is formed, and dicing areas A2 to be removed by dicing at the time of singulation.

The device area A1 includes the die pad 12 serving as a chip mounting portion capable of supporting the semiconductor chip 20, and the plurality of lead portions 11 arranged around the die pad 12. The lead portions 11 in the device area A1 are the rectangular portions 11a and the tip portions 11b described above. The lead portions 11 in the dicing areas A2 are connecting portions 11c to serve as cutting margins at the time of singulation by dicing, and integrally hold a plurality of the semiconductor devices 100 until the singulation.

### <2. Semiconductor Chip Mounting Step>

Next, as illustrated in FIG. 7B, the semiconductor chip 20 is mounted on the upper surface of the die pad 12. The semiconductor chip 20 is bonded to the die pad 12 with the die bonding material 30.

### <3. Wire Bonding Step>

Next, as illustrated in FIG. 7C, the bonding pads provided on the upper surface of the semiconductor chip 20 and the rectangular portions 11a of the lead portions 11 are electrically connected with the wires 40.

### <4. Resin Molding Step>

Next, as illustrated in FIG. 7D, the entire surface of the lead frames 10 is collectively covered by the encapsulating resin 50. In other words, a gap between the lead portions 11 and the die pad 12 is also filled with the encapsulating resin 50. In contrast, it is ensured that a bottom surface of the lead frame 10 is not covered by the encapsulating resin 50.

### <5. Resin Removing Step>

Next, as illustrated in FIG. 7E, the encapsulating resin 50 near the connecting portion 11c is removed with laser L which is irradiated in a +Z direction while the laser L is scanned in the X direction, to thereby expose the second exposed surfaces 11bb. As an intensity of the laser L, there is used an intensity of a level at which the encapsulating resin 50 can be removed, and the lead portions 11 cannot be removed even when the lead portions 11 are irradiated with the laser L. In this manner, the encapsulating resin 50 is removed with use of the laser L so that “L2>L3” is established, to thereby form the step 100b illustrated in FIG. 2 as illustrated in FIG. 7F.

A scanning path of the laser L may be a path on which the laser L is irradiated repeatedly in one direction, or a path on which the laser L is irradiated while reciprocating.

A range in which the encapsulating resin 50 is removed by the laser L may be only near both ends of the connecting portion 11c, and portions serving as the cutting margins during dicing may not be removed.

An angle at which the laser L is irradiated may be a normal direction with respect to the surface of the lead frame 10, or may be slightly adjusted from the normal direction to adjust a range of exposed regions of the second exposed surfaces 11bb. Exposed areas of the second exposed surfaces 11bb may be adjusted by adjusting the intensity of the laser L.

It is preferred that, after the resin is removed by being irradiated with the laser L, a residual resin which is the remainder of the encapsulating resin that is left unremoved be removed.

As a method of removing the residual resin, water jetting or liquid honing is preferred in that the method can be easily performed in an existing process.

In a case in which the water jetting is performed, liquid is injected from a nozzle to remove the residual resin. In ae case in which the liquid honing is performed, slurry is injected from an injection gun and sprayed on the adhering residual resin to remove the residual resin.

The removal of the residual resin may be performed in a range of usable dimensions that contribute to solder joint at the time of mounting.

### <6. Metal Film Forming Step>

Next, the metal film 60 having satisfactory solder wettability is formed by soldering, for example, on the bottom surfaces of the lead portions 11 and the die pad 12, and on a part of the lead portions 11 exposed by the removal of the resin.

The metal film forming step may not be performed if solder wettability of the lead portions 11 per se is satisfactory.

### <7. Singulation Step>

Next, as illustrated in FIG. 7G, the connecting portion 11c is cut by a dicing saw D for singulation, and as a result, the semiconductor device 100 having the lead portions 11 as illustrated in FIG. 2 can be obtained. Thus, the first exposed surface 11ba being a surface cut by the dicing saw D is not covered by the metal film 60.

Through the execution of the steps described above, the semiconductor device 100 can be manufactured.

As described above, the semiconductor device 100 is covered by the encapsulating resin 50 into the cuboid shape, and the plurality of lead portions 11 are partially exposed from the side surfaces 100c and the bottom surface 100a. In other words, the semiconductor device 100 has the step 100b formed in the encapsulating resin 50 along the edges formed by the side surfaces 100c and the bottom surface 100a. Each of the lead portions 11 has the first exposed surface 11ba which is coplanar with the side surfaces 100c, and is exposed from the side surfaces 100c, and the second exposed surfaces 11bb which are surfaces that are adjacent to and on both sides of the first exposed surface 11ba, and are exposed from the step 100b.

As a result, the semiconductor device 100 can increase the bonding strength with respect to the mounting substrate.

### Modification Example of First Embodiment

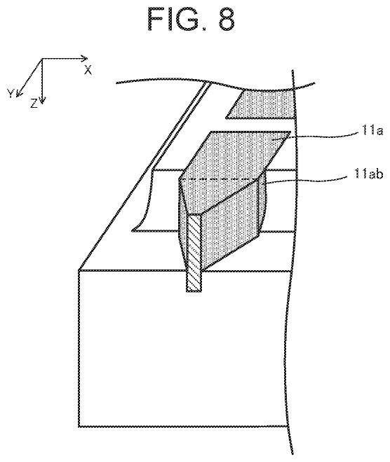

FIG. 8 is a perspective view for illustrating the structure on a mounting surface side of a semiconductor device according to a modification example of the first embodiment.

As illustrated in FIG. 8, a semiconductor device 100 according to the modification example of the first embodiment is similar to the semiconductor device 100 according to the first embodiment except that side surfaces 11ab of the rectangular portion 11a are exposed in the semiconductor device 100 according to the first embodiment.

With this configuration, because the semiconductor device 100 according to the modification example of the first embodiment is joined with the solder S in a larger area in a lead portion 11, bonding strength with respect to a mounting substrate B can be further increased.

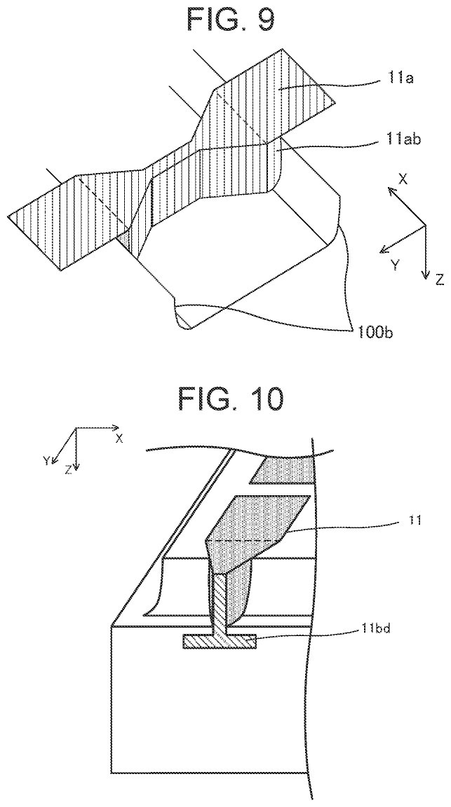

A method of manufacturing the semiconductor device 100 according to the modification example of the first embodiment is similar to the method of manufacturing the semiconductor device 100 according to the first embodiment except that, as illustrated in FIG. 9, the encapsulating resin 50 is removed to widen the width of the step 100b and expose the side surfaces 11ab of the rectangular portion 11a in the resin removing step of the first embodiment, and a metal film 60 is formed also on the side surfaces 11ab in the metal film forming step.

### Second Embodiment

FIG. 10 is a perspective view for illustrating the structure on a mounting surface side of a semiconductor device according to a second embodiment of the present invention.

As illustrated in FIG. 10, a semiconductor device 100 according to the second embodiment is similar to the semiconductor device 100 according to the first embodiment except for including a reinforcing structure portion 11bd on an upper surface side of the lead portion 11 in the first embodiment.

In this manner, the semiconductor device 100 according to the second embodiment can increase mechanical strength of the lead portion 11 by providing the reinforcing structure portion 11bd.

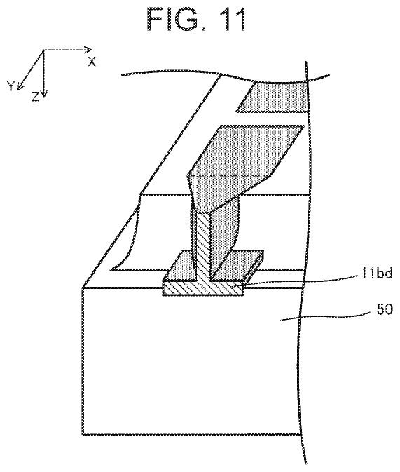

Further, according to a modification example of the second embodiment, as illustrated in FIG. 11, the encapsulating resin 50 is removed deeply to a state in which the reinforcing structure portion 11bd is exposed, to thereby expose the reinforcing structure portion 11bd. As a result, the bonding strength can be increased because a fillet is formed also on the exposed reinforcing structure portion 11bd.

Although the embodiments of the present invention have been specifically described above, the present invention is not limited to the embodiments described above. It should be understood that various modifications can be made within the scope of the gist of the present invention.

For example, in each of the embodiments described above, a 6-pin DFN package is adopted as an example of a semiconductor device of a leadless type. However, the present invention is not limited thereto, and Quad-Flat Non-leaded (QFN) package may be adopted, for example.

Further, each of the embodiments described above employs the structure in which the die pad is exposed from the bottom surface of the semiconductor device, but may employ the structure in which the die pad is not exposed from the bottom surface of the semiconductor device.

Still further, in each of the embodiments described above, the shape of the lead portion is a shape obtained by integrating the rectangular portion having the rectangular shape and the tip portion having the trapezoid shape in plan view of the bottom surface of the semiconductor device. However, the present invention is not limited thereto as long as the shape can provide the first exposed surface and the second exposed surfaces.

Yet further, in each of the embodiments described above, the shape of the cutout portions is the step 100b having the curved surfaces. However, the present invention is not limited thereto as long as the cutout shape can provide the first exposed surface and the second exposed surfaces.

What is claimed is:

1. A semiconductor device which is covered by an encapsulating resin into a cuboid shape, and has a plurality of lead portions partially exposed from side surfaces and a bottom surface thereof,
the semiconductor device having cutout portions formed in the encapsulating resin along edges formed by the side surfaces and the bottom surface,
each of the plurality of lead portions having:
a first exposed surface which is coplanar with one of the side surfaces, and is exposed from the one of the side surfaces; and
second exposed surfaces which are surfaces that are adjacent to and on both sides of the first exposed surface, and are exposed from one of the cutout portions.

2. The semiconductor device according to claim 1, wherein the second exposed surfaces are covered by a metal film having solder wettability.

3. The semiconductor device according to claim 1, wherein an angle formed by the first exposed surface and each of the second exposed surfaces is an obtuse angle.

4. The semiconductor device according to claim 1, wherein a height of the cutout portions in the side surfaces is equal to or less than a height of the first exposed surface.

5. The semiconductor device according to claim 1, wherein the cutout portions form a step having a planar surface that is parallel to the bottom surface.

6. The semiconductor device according to claim 2, wherein an angle formed by the first exposed surface and each of the second exposed surfaces is an obtuse angle.

7. The semiconductor device according to claim 2, wherein a height of the cutout portions in the side surfaces is equal to or less than a height of the first exposed surface.

8. The semiconductor device according to claim 2, wherein the cutout portions form a step having a planar surface that is parallel to the bottom surface.

9. The semiconductor device according to claim 3, wherein a height of the cutout portions in the side surfaces is equal to or less than a height of the first exposed surface.

10. The semiconductor device according to claim 3, wherein the cutout portions form a step having a planar surface that is parallel to the bottom surface.

11. The semiconductor device according to claim 4, wherein the cutout portions form a step having a planar surface that is parallel to the bottom surface.
